(19) United States
(12) Patent Application Publication
(10) Pub. No.: US 2020/0068734 A1
(43) Pub. Date: Feb. 27, 2020

(54) HOUSING PART FOR A HOUSING OF ELECTRIC COMPONENTS

(71) Applicant: Phoenix Contact GmbH & Co. KG, Blomberg (DE)

(72) Inventors: Joachim Bury, Herford (DE); Thomas Salomon, Verl (DE)

(21) Appl. No.: 16/466,384

(22) PCT Filed: Dec. 1, 2017
(86) PCT No.: PCT/EP2017/081266

§ 371 Date: Jun. 4, 2019

(30) Foreign Application Priority Data
Dec. 8, 2016 (DE) 10 2016 123 759.0

(51) Int. Cl. H05K 5/02; H05K 5/06

(52) U.S. Cl. CPC H05K 5/0247; H05K 5/069

(57) ABSTRACT

The present disclosure relates to a housing part for a housing of electric components having a first universal connection device configured as an interface for electric components inside the housing, and an application-specific adapter flange configured to be arranged on the connection device and as an interface for the electric components inside the housing.

### CROSS-REFERENCE TO RELATED APPLICATIONS

This application is a 371 national phase filing of International Application No. PCT/EP2017/081266, entitled “HOUSING PART FOR A HOUSING OF ELECTRIC COMPONENTS”, filed 1 Dec. 2017, which claims priority to German Patent Application No. 10 2016 123 759.0, entitled “GEHÄUSETEIL FÜR EIN GEHÄUSE ELEKTRISCHER BAUTEILE”, filed 8 Dec. 2016.

### BACKGROUND

The present disclosure relates to a housing part for a housing of electric components having a connection device which is configured as an interface for electric components inside the housing.

Such housing parts or housing designs for electric components usually comprise a plurality of fixed interfaces configured for different screw connections or line inlets into or out of the housing, Universal housings or housing upper and lower shells are thereby often used in combination with additional connection couplings in order to enable application-specific interface variances. A desired interface is in each case thereby provided by arranging the respective geometrical connection contour at a location on a housing shell provided for same. Disadvantageous with this principle, however, is that many different tool inserts are needed for all the design variants when producing the housing parts.

Printed publication DE 299 22 206 U1 describes a plug coupling system for the connection of an electric component enclosed in a housing, in particular a sensor.

Printed publication DE 36 25 500 A1 describes a front-plug connecting system in which different connection technologies can be used to embed and lock connecting elements into the contact clips of a front-plug housing.

### SUMMARY

It is the task of the present disclosure to provide an improved concept for a housing part with a universal interface.

This task is solved by the subject matter having the features as per the independent claims. Advantageous examples of the present disclosure constitute the subject matter of the figures, the description and the dependent claims.

According to one aspect of the present disclosure, the task is solved by a housing part for a housing of electric components comprising a first universal connection device which is configured as an interface for electric components inside the housing and an application-specific adapter flange which is configured to be arranged on the first connection device and as an interface for the electric components inside the housing. This thereby achieves the technical advantage of, for example, being able to produce each desired interface at just one single location on a housing for electric components from a plurality of different adapter flanges by means of a universal connection device in conjunction with an application-specific adapter flange. Particularly advantageous hereby is that producing the respective housing parts with a single universal interface is economical and uses fewer tool inserts. The housing parts can thus be correspondingly tailored to the application requirements independent of tool.

In order to configure particularly high universal interface flexibility, the adapter flange is interchangeably configured. It is thus possible to arrange a preferred adapter flange corresponding to the respective application purpose on the first connection device. The adapter flange interchangeability additionally enables varying the function car application by changing the adapter flange.

According to one example, the adapter flange comprises a screw-on socket for screw connections. This thereby achieves the technical advantage of, for example, enabling very simple and flexible arranging of the adapter flange on the first connection device.

According to a further example, the adapter flange is configured to accommodate metric connection fittings. For example, M16, M20 or M25 size screw connections may thereby be used. This thereby achieves the technical advantage of, for example, the screw connections being particularly easily producible with existing tool inserts. It is thus possible to make use of existing means in the production. However, providing the screw connection in other sizes or formats is just as conceivable.

In order to design a particularly reliable adapter flange arrangement, the adapter flange is configured as a mount housing for a plug connector. Particularly suitable here are the HC-Q5 or HC-Q8 industrial plug connectors, for example. Such plug connectors are moreover particularly resistant to humidity, heat or any potential environmental influences.

According to a further example, the adapter flange is configured to completely cap the first connection device. This thereby achieves the technical advantage of, for example, being able to completely close a housing carrying electric components when needed. This may be the case for example during assembly of the housing or when replacing such a housing. Such a housing can furthermore be reliably closed for transport, whereby the electric components in the interior can be protected against humidity.

In order to improve the reliability and the tightness of the connection between the first connection device and the adapter flange, and in particular to prevent moisture from infiltrating, the housing part comprises a sealing element to seal the first connection device and the adapter flange from one another.

According to one example, the sealing element is configured as an O-ring and arranged between the first connection device and the adapter flange. Such O-rings are inexpensive to produce and effective in their action.

In order to secure the adapter flange particularly reliably and stably, the adapter flange comprises fixing means to fix the adapter flange to the housing part. Screws are particularly simple and effective for this purpose. The screws can thereby create a connection between the adapter flange and the first connection device, although it would be just as conceivable for the screws to connect the adapter flange directly to the housing part or the housing.

In one preferential example, the fixing means is configured as a manually operable clamping device. This thereby achieves the technical advantage of, for example, enabling an adapter flange change very quickly and without the use of a tool.

In a still further example, the first connection device and the housing part are integrally configured as an integral component. This substantially simplifies the production and the manufacturing costs of the housing part since fewer individual components need to be manufactured and assembled.

According to a still further example, the first connection device is arranged screwable to the housing part. This thereby achieves the technical advantage of, for example, enabling very easy arranging of the first connection device on housing parts. The first connection device can additionally be removed from the housing part and replaced.

In order to increase the flexibility and the range of applications of the housing part, the housing part comprises at least one second connection device and a further adapter flange. The second connection device can thereby be connected to the same adapter flange. It is however likewise conceivable for the first connection device and the second connection device to be equipped with respectively different adapter flanges. The different interfaces can thereby also be arranged on different housing parts of a housing for electric components according to need.

In a further example, the connection device is configured to positively overlap the adapter flange. This thereby achieves the technical advantage of, for example, protecting the inner seal and the connection being resistant to contamination and having a high mechanical load capacity.

To realize the ease of operation of the adapter flange and the connection device as well as cost-effective production and installation, the adapter flange and the connection device are interlockably configured.

According to a further aspect of the present disclosure, the task is solved by a method for producing a housing part for a housing of electric components comprising the steps of providing a housing part for a housing with a connection device configured as an interface for electric components inside a housing and arranging a specific adapter flange from a plurality of adapter flanges on the connection device in order to create a preferred interface to the electric components inside a housing. This thereby achieves the technical advantage of, for example, being able to create any desired interface at a single location on a housing for electric components by means of the universal connection device in conjunction with a specific adapter flange from among a plurality of different adapter flanges. Particularly advantageous thereby is enabling economical production of the corresponding housing parts with a single universal interface and the use of fewer tool inserts. This thus enables the tool-independent tailoring of housing parts.

### BRIEF DESCRIPTION OF THE DRAWINGS

Further examples of the present disclosure are depicted in the drawings and will be described in greater detail below.

FIG. 1 shows a perspective representation of a housing with a housing part,

FIG. 2 shows a further perspective representation of a housing with a housing part,

FIG. 3 shows a further perspective representation of a housing with a housing part,

FIG. 4 shows a schematic sectional representation of a housing with a housing part,

FIG. 5A shows a perspective representation of a connection device,

FIG. 5B shows a perspective representation of an adapter flange,

FIG. 5C shows a further perspective representation of an adapter flange,

FIG. 5D shows a further perspective representation of an adapter flange,

FIG. 5E shows a further perspective representation of an adapter flange,

FIG. 5F shows a further representation of a connection device,

FIG. 6 shows a further perspective representation of a housing with a housing part, and

FIG. 7 shows a further perspective representation of a housing with a housing part.

### DETAILED DESCRIPTION

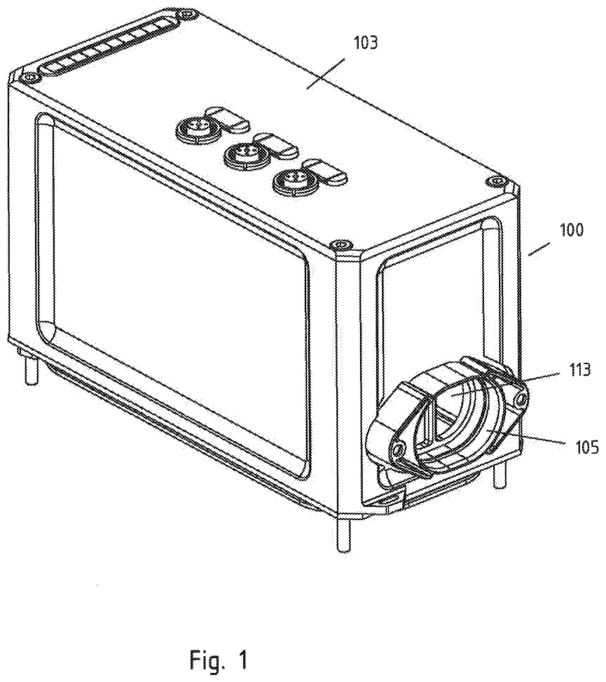

FIG. 1 shows a perspective representation of a housing 103 having a housing part 100. The housing part 100 is configured as part of a housing 103 for electric components. The housing part 100 comprises a first connection device 105 configured as an interface for the electric components inside the housing 103. The connection device 105 is thereby arranged directly on an opening 113 provided, for example, by removing a knockout area. However, it is alternatively just as possible for the first connection device 105 and the housing part 100 to be integrally configured as an integral component. In certain applications, it would also be conceivable for the first connection device 105 to be arranged screwable to the housing part 100 and thus easily replaceable.

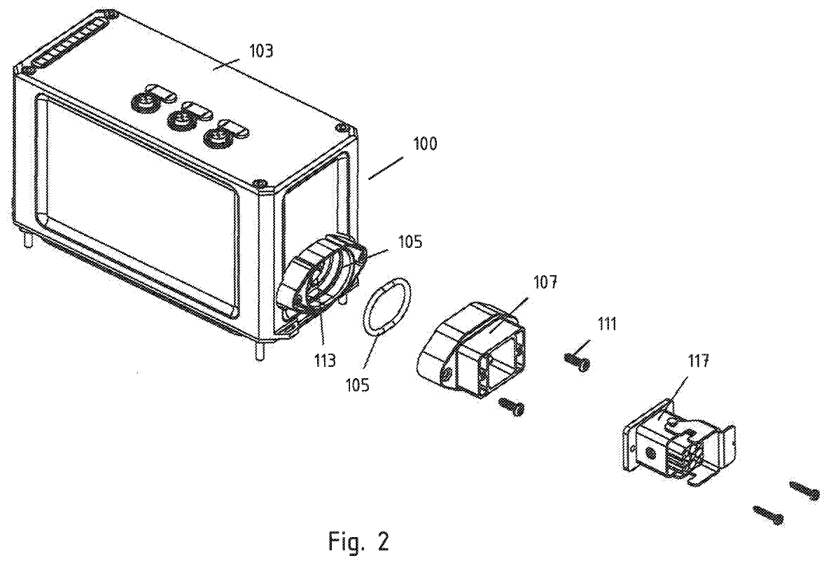

FIG. 2 shows a further perspective representation of a housing 103 having a housing part 100. The housing part 100 is likewise configured as part of the housing 103 for electric components and comprises the first connection device 105 as an interface for the electric components inside the housing 103. The housing part 100 additionally comprises an adapter flange 107 configured for arranging on the connection device 105 and as an interface for the electric components inside the housing 103.

The adapter flange 107 is configured as a mount housing for a plug connector 117 and secured to the housing part 100 by fixing means 111. The fixing means 111 thereby comprises two screws which can be alternatively configured as, for example, a manually operable clamping device. A sealing element 109 in the form of an O-ring is arranged between the first connection device 105 and the adapter flange 107. This considerably improves the tightness of the housing part 100.

FIG. 3 shows a further perspective representation of a housing 103 having a housing part 100. The housing part 100 is again part of a housing 103 for electric components and comprises the first connection device 105 configured as an interface for the electric components inside the housing 103. The adapter flange 107 is configured as a mount housing for a plug connector 117. The housing part 100 additionally comprises a second connection device 106, which is equipped with a further adapter flange 107 and exhibits an internal thread.

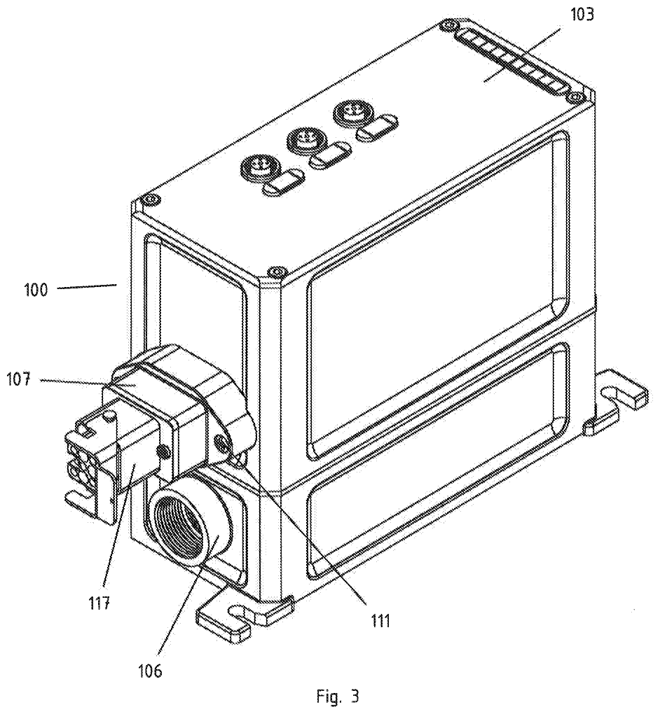

FIG. 4 shows a schematic sectional representation of a housing 103 having a housing part 100. The housing part 100 is again part of a housing 103 and comprises the first connection device 105. The adapter flange 107 is configured as a mount housing for a plug connector 117. The housing 103 additionally comprises a second connection device 106, which is arranged on the housing 103 on the opposite side from the first connection device 105. The sealing element 109 in the form of an O-ring is arranged between the first connection device 105 and the adapter flange 107.

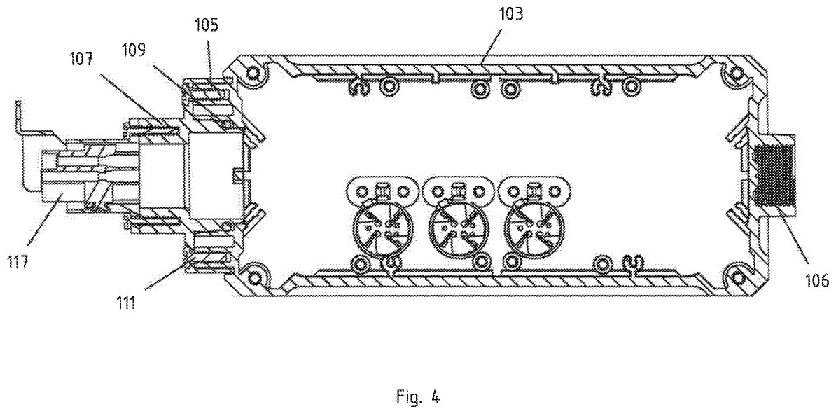

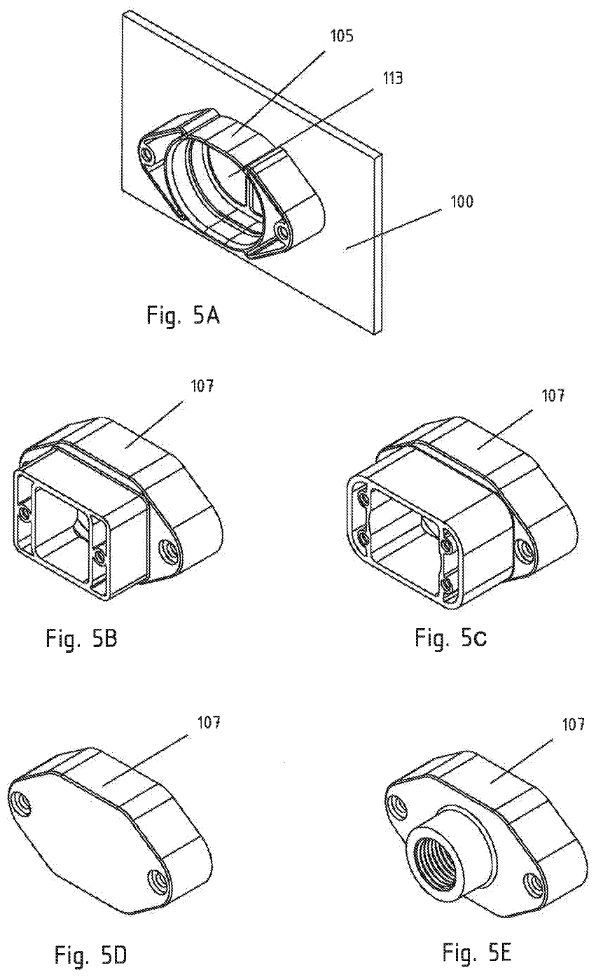

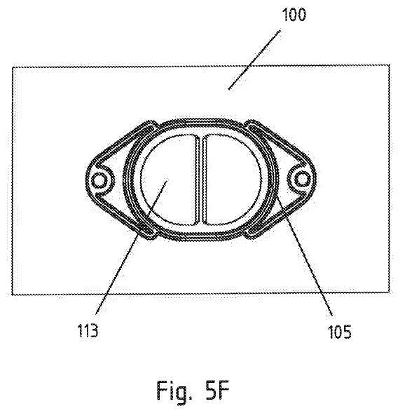

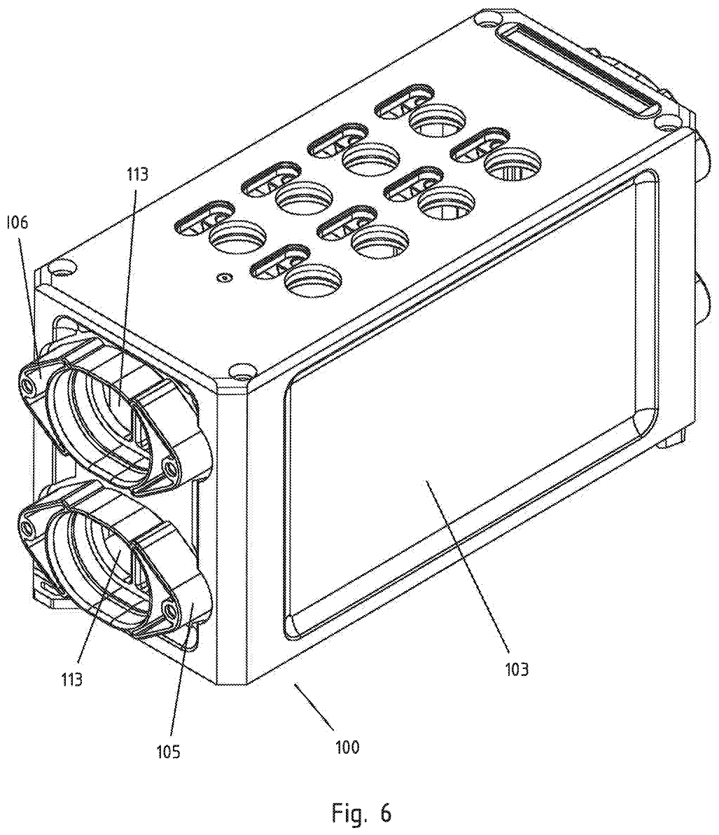

FIGS. 5A to 5F show different perspective representations of connection devices 105 or adapter flanges 107. Due to the required flexibility of the interface, the adapter flange 107 is interchangeably configured.

FIG. 5A shows a perspective representation of a first connection device 105 as configured on the housing part 100 of a housing 103 for electric components.

FIG. 5B shows a perspective representation of an adapter flange 107 in the form of a HanQ5 plug connector as may be arranged on the first connection device 105.

FIG. 5C shows a further perspective representation of an adapter flange 107 in the form of a HanQ8 plug connector as may be arranged on the first connection device 105.

FIG. 5D shows a further perspective representation of an adapter flange 107 which is configured to completely cap the first connection device 105.

FIG. 5E shows yet a further perspective representation of an adapter flange 107 which comprises a threaded socket for screw connections. The internal thread of the threaded socket can for example be configured to receive M16, M20 or M25 size screw connections.

FIG. 5F shows a representation from above of a first connection device 105 as configured on the housing part 100 of a housing 103 for electric components.

FIG. 6 shows a further perspective representation of a housing 103 having a housing part 100. The housing part 100 is again part of the housing 103 for electric components and comprises the first connection device 105 configured as an interface for the electric components inside the housing 103. The housing part 100 additionally comprises a second connection device 106. The first connection device 105 and the second connection device 106 are both arranged in parallel alignment on the housing part 100.

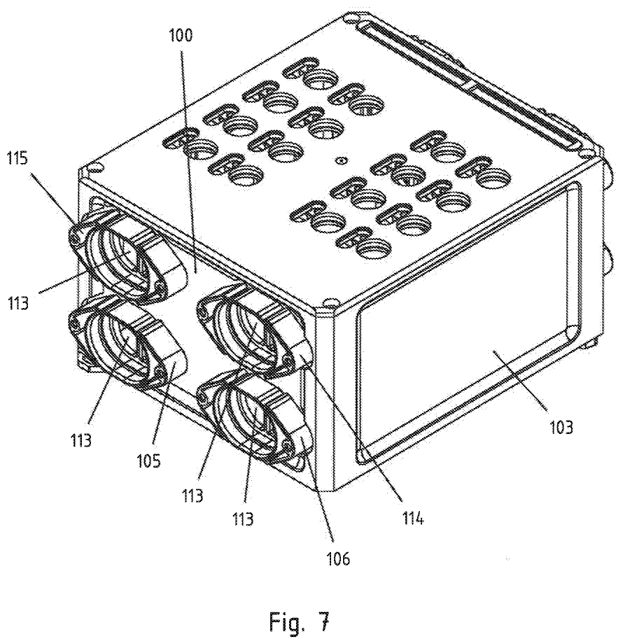

FIG. 7 shows a further perspective representation of a housing 103 having a housing part 100. The housing part 100 is part of the housing 103 for electric components and comprises the first connection device 105 as the interface for the electric components inside the housing 103. The housing part 100 additionally comprises a second connection device 106, a third connection device 114 and a fourth connection device 115. All the connection devices are arranged in parallel alignment on the housing part 100.

All of the features described and shown in connection with individual examples of the present disclosure can be provided in different combinations in the inventive subject matter so as to realize their advantageous effects simultaneously.

### LIST OF REFERENCE NUMERALS

100 housing part
103 housing
105 first connection device
106 second connection device
107 adapter flange
109 sealing element
111 fixing means
113 opening
114 third connection device
115 fourth connection device
117 plug connector

What is claimed is:

1. A housing part for a housing of electric components, comprising:
a first universal connection device configured as an interface for electric components inside the housing and an application-specific adapter flange configured to be arranged on the first universal connection device and as an interface for the electric components inside the housing.

2. The housing part according to claim 1, wherein the adapter flange is interchangeable.

3. The housing part according to claim 1, wherein the adapter flange comprises a screw-on socket for screw connections.

4. The housing part according to claim 3, wherein the adapter flange is configured to accommodate metric connection fittings.

5. The housing part according to claim 1, wherein the adapter flange is configured as a mount housing for a plug connector.

6. The housing part according to claim 1, wherein the adapter flange is configured to completely cap the first connection device.

7. The housing part according to claim 1, wherein the housing part comprises a sealing element configured to seal the first connection device and the adapter flange from one another.

8. The housing part according to claim 1, wherein the adapter flange comprises a fastener configured to fix the adapter flange to the housing part.

9. The housing part according to claim 8, wherein the fastener comprises a manually operable clamping device.

10. The housing part according to claim 1, wherein the first connection device and the housing part are formed as an integral component.

11. The housing part according to claim 1, wherein the first connection device is configured to screw to the housing part.

12. The housing part according to claim 1, wherein the first connection device is configured to positively overlap the adapter flange.

13. The housing part according to claim 1, wherein the adapter flange and the first connection device are interlockably configured.

14. The housing part according to claim 1, wherein the housing part comprises at least one second connection device and a further adapter flange.

15. A method for producing a housing part, comprising:
providing a housing part for a housing with a connection device configured as an interface for electric components inside a housing,
arranging a specific adapter flange from a plurality of adapter flanges on the connection device to create an interface to the electric components inside the housing.

16. The method of claim 15, wherein arranging the specific adapter flange comprises exchanging a different adapter flange from the plurality of adapter flanges for the specific adapter flange.

17. The method of claim 15, wherein arranging the specific adapter flange comprises:
screwing the adapter flange onto the connection device:

18. The method of claim 15, wherein arranging the specific adapter flange comprises:
fastening the adapter flange to the housing part using a manually operable clamping device.

19. The method of claim 15, further comprising:
screwing the first connection device to the housing part.

20. The method of claim 15, wherein arranging the specific adapter flange on the connection device comprises:
interlocking the adapter flange with the first connection device.
